(19) United States
(12) Patent Application Publication
(10) Pub. No.: US 2024/0213932 A1
(43) Pub. Date: Jun. 27, 2024

(54) Multi-Input LNA with Passive Bypass Gain Modes

(71) Applicant: pSemi Corporation, San Diego, CA (US)

(72) Inventors: Rong Jiang, Rohnert Park, CA (US); Sung Kyu Han, San Diego, CA (US); Parvez H. Daruwalla, San Diego, CA (US); Khushali Shah, San Diego, CA (US)

(21) Appl. No.: 18/087,476

(22) Filed: Dec. 22, 2022

(51) Int. Cl. H03F 3/193; H03F 1/56; H03H 7/38

(52) U.S. Cl. CPC H03F 3/193; H03F 1/565; H03H 7/38; H04B 1/406

(57) ABSTRACT

New multi-input LNA architectures with improved passive mode negative gain performance that reconfigure the bypass path routes to achieve wide-band bypass matching and make bypass matching for lower frequency bands possible to achieve desired gain specifications. In a first embodiment, improved wide-band performance is provided by a bypass path that optionally does not pass through an impedance matching network and thus has a dedicated path to RF_{OUT}. In a second embodiment, improved wide-band performance is provided by a bypass path that does not pass through an input inductor. In a third embodiment, improved wide-band performance is provided by a bypass path that has a first portion that optionally does not pass through an impedance matching network, and a second portion that does not pass through an input inductor. In a fourth embodiment, improved wide-band performance is provided by selectively disabling a load inductor in some modes of operation.

### BACKGROUND

### (1) Technical Field

The invention relates to electronic circuits, and more particularly to radio frequency amplifier circuits.

### (2) Background

Many modern electronic systems include radio frequency (RF) receivers; examples include cellular telephones, personal computers, tablet computers, wireless network components, televisions, cable system “set top” boxes, and radar systems. Many RF receivers are paired with RF transmitters in the form of transceivers, which often are quite complex two-way radios. In some cases, RF transceivers are capable of transmitting and receiving across multiple frequencies in multiple bands.

Amplifiers are a common component in RF transmitters, receivers, and transceivers, and are frequently used for power amplification of transmitted RF signals and for low-noise amplification of received RF signals. For many RF systems, particularly those requiring low power and/or portability (e.g., cellular telephones, WiFi-connected computers, cameras, and other devices), it has become common to use complementary metal-oxide semiconductor (CMOS) fabrication technology to create low cost, low power integrated circuits (ICs). CMOS devices include bulk CMOS, silicon-on-insulator (SOI) CMOS, and silicon-on-sapphire (SOS) CMOS (SOS being a type of SOI fabrication technology).

Receiving an RF signal in many environments requires a high quality low-noise amplifier (LNA) as part of an RF “front end” (RFFE) receiver or transceiver chain of circuits. Important desired characteristics of an LNA are high gain with low noise, a wide bandwidth, good linearity, and good input and output impedance matching. However, in general, all of these factors cannot be optimized simultaneously, and accordingly there are tradeoffs between these characteristics when designing an LNA.

Five important design parameters for LNAs are gain, noise figure (NF), input-referenced third intercept point (IIP3), output reflection coefficient, and input reflection coefficient. NF is a measure of degradation of the signal-to-noise ratio (SNR) caused by components in a signal chain, with lower values indicating better performance. IIP3 is a figure of merit representing amplifier linearity, with higher values indicating better performance. In general, NF has a stricter specification requirement in high-gain modes than in low gain-modes, while IIP3 has a stricter specification requirement in low-gain modes than in high-gain modes. The output reflection coefficient is the S22 scattering parameter (or “S-parameter”) and is an indication of output impedance matching, with lower (more negative, when evaluated logarithmically) numbers indicating better impedance matching. The input reflection coefficient is the S11 S-parameter and is an indication of input impedance matching, with lower (more negative, when evaluated logarithmically) numbers indicating better performance.

Increases in the frequency of RF communications bands and channels, as well as a continuing increase in the number of bands and channels in use, has pushed current LNA architectures to their limits. For example, achieving stringent requirements for gain, percentage bandwidth, linearity, and input and output impedance matching with a traditional LNA architecture is difficult, and sometimes impossible, for some of the new 5G mobile network bands, particularly in the 3 to 6 GHz NR bands, the upcoming 7-24 GHz bands, and the millimeter wave range (e.g., 24.25 GHZ to 52.6 GHz), owing to insufficient wide-band performance (e.g., “wide-band” meaning a bandwidth from about 1.4 GHz to about 2.7 GHZ).

Wide-band LNAs present several design challenges. For example, achieving effective wide-band impedance matching at the input of an LNA is a key objective for attaining overall performance, especially NF. Known approaches to input impedance (IM) matching involve using a series inductor between an LNA input terminal and the amplification core (e.g., a cascode transistor pair) but those solutions have limited bandwidth.

For example, FIG. 1 is a simplified schematic diagram of a first embodiment of a prior art LNA circuit 100. In the illustrated example, the LNA circuit 100 includes an amplifier core 102 comprising a stack of two series-connected FETs M_{CS}. M_{CG} in a cascode arrangement. An RF input signal applied to an RF input terminal RF_{IN} is coupled through a series input matching inductor L1 and a DC blocking capacitor C_{IN} to the control gate of the common-source FET M_{CS}, which may be regarded as an input terminal INT of the amplification core 102. (As used herein, unless the context requires otherwise, “matching” means “impedance matching”.)

The source of the common-gate FET M_{CG} is connected to the drain of the common-source FET M_{CS}. The drain of the common-gate FET M_{CG} provides an amplified RF output signal at what may be regarded as an amplified-signal terminal AST of the amplification core 102. A first bias circuit (not shown) may be included to provide a suitable bias voltage CG_V_{BIAS} to the common-gate FET M_{CG} and a second bias circuit (not shown) may be included to provide a suitable bias voltage CS_V_{BIAS} to the common-source FET M_{CS}. In the illustrated example, the amplified-signal terminal AST is coupled to a voltage source V_{DD} through an inductor L2 and to an RF output terminal RF_{OUT} and through an output capacitor C_{OUT}. The RF output terminal RF_{OUT} would typically be coupled to a 50-ohm load for many modern RF circuits. An inductor L3 is coupled between what may be regarded as a degeneration terminal DT of the amplification core 102 and a reference potential, such as circuit ground.

The illustrated example includes a bypass and input matching (IM) feedback circuit 104. An IM feedback portion of the bypass/IM feedback circuit 104 is coupled between the amplified-signal terminal AST (through a capacitor C_{BP}) and the input terminal INT (through capacitor C_{IN}), and in the illustrated example includes a resistor R_{FB} series-coupled to a switch S_{FB}1, the combination of which is series-coupled between capacitor C_{BP} and capacitor C_{IN}. In some embodiments, C_{BP} and/or R_{FB} may be adjustable or have fixed values. The IM feedback portion of the bypass/IM feedback circuit 104 may be enabled by closing switch S_{FB}1 and disabled by opening switch S_{FB}1.

A bypass portion of the bypass/IM feedback circuit 104 accommodates strong RF input signals that do not need amplification, allowing such signals to be coupled more directly to RF_{OUT}. The bypass portion includes switches S_{FB}2 and S_{FB}3 coupled in series between capacitor C_{BP} and capacitor C_{IN}. An AC ground is coupled by a switch S_{FB}4 to a midpoint node between switches S_{FB}2 and S_{FB}3. Switches S_{FB}2 and S_{FB}3 may both be CLOSED (OFF) and switch S_{FB}4 OPENED (ON) to create a passive AC bypass path from RF_{IN} through switches S_{FB}2 and S_{FB}3 and capacitors C_{BP} and C_{OUT} to RF_{OUT}. When the bypass mode is OFF, switches S_{FB}2 and S_{FB}3 are OPEN (ON) and switch S_{FB}4 is CLOSED (OFF) to improve isolation. The passive AC bypass path is tied to the LNA load to achieve bypass matching.

Most of the components shown in FIG. 1 would be fabricated as part of an integrated circuit (IC) and thus be “on-chip”. However, due to its relative large size, the input matching inductor L1 generally would be an external or “off-chip” component coupled to a connection “bump” 106 of the IC embodying the remaining circuitry.

The basic embodiment of FIG. 1 is suitable only for narrow-band performance. For wide-band implementation, due to large parasitics at the input node, the S11 and S22 parameters cannot achieve reasonable values with existing matching components. To increase bandwidth, an optional on-chip inductor L4 may be coupled to the midpoint node between switches S_{FB}2 and S_{FB}3. When the passive bypass path is enabled, the inductor L4 resonates the parasitic capacitance at the node where inductor L4 is connected, although the Q of inductor L4 is low. However, due to the large input matching inductor L1 needed for the lower frequencies (e.g., around 1.5 GHZ) of a wide-band range, S11 and S22 parameter matching is very challenging even in the modified LNA circuit 100.

TABLE 1 summarizes the passive mode negative gain for a modeled embodiment of the LNA circuit 100.

TABLE 1

| | Center of Band Gain (dB) |
|---|---|
| Band (GHz) | [with L4] |
| 1.4-1.5 | −13.84 |
| 1.8-2.0 | −7.97 |
| 2.0-2.2 | −6.56 |
| 2.3-2.4 | −4.74 |
| 2.5-2.7 | −4.30 |

More generally, it is very challenging to achieve reasonable passive mode negative gain (−3 dB or even −6 dB, for example) for lower frequency bands in a very wide-band LNA which uses a large series inductor L1 for input matching. Accordingly, there is a need for an LNA architecture that overcomes the limitations of conventional LNA architectures.

### SUMMARY

The present invention encompasses new multi-input LNA architectures with improved passive mode negative gain performance that reconfigure the bypass path routes to achieve wide-band bypass matching and make bypass matching for lower frequency bands possible to achieve desired gain specifications.

In a first embodiment, improved wide-band performance is provided in part by a bypass path that optionally does not pass through an impedance matching network and thus has a dedicated path to RF_{OUT}.

In a second embodiment, improved wide-band performance is provided in part by a bypass path that does not pass through an input inductor.

In a third embodiment, improved wide-band performance is provided in part by a bypass path that has a first portion that optionally does not pass through an impedance matching network and thus has a dedicated path to RF_{OUT}, and a second portion that does not pass through an input inductor.

In a fourth embodiment, improved wide-band performance is provided in part by selectively disabling a load inductor in some modes of operation.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a simplified schematic diagram of a first embodiment of a prior art LNA circuit.

FIG. 2 is a simplified schematic diagram of a first embodiment of an LNA circuit with improved wide-band performance.

FIG. 3 is a schematic diagram of an example variable capacitor circuit.

FIG. 4 is a schematic diagram of an example variable resistor circuit.

FIG. 5A is a schematic diagram of a first example variable inductor circuit.

FIG. 5B is a schematic diagram of a second example variable inductor circuit.

FIG. 6 is a schematic diagram of an example amplifier core that may include a FET stack.

FIG. 7 is a simplified schematic diagram of a second embodiment of an LNA circuit with improved wide-band performance.

FIG. 8 is a simplified schematic diagram of a third embodiment of an LNA circuit with improved wide-band performance.

FIG. 9 is a simplified schematic diagram of a fourth embodiment of an LNA circuit with improved wide-band performance.

FIG. 10 is a top plan view of a substrate that may be, for example, a printed circuit board or chip module substrate (e.g., a thin-film tile).

FIG. 11 illustrates a prior art wireless communication environment comprising different wireless communication systems, and which may include one or more mobile wireless devices.

FIG. 12 is a block diagram of a transceiver that might be used in a wireless device, such as a cellular telephone, and which may beneficially incorporate an embodiment of the present invention for improved performance.

Like reference numbers and designations in the various drawings indicate like elements.

### DETAILED DESCRIPTION

The present invention encompasses new multi-input LNA architectures with improved passive mode negative gain performance that reconfigure the bypass path routes to achieve wide-band bypass matching and make bypass matching for lower frequency bands possible to achieve desired gain specifications. In general, a “multi-input LNA” means a single LNA block have multiple selectable inputs, each input having access to shared and/or dedicated bypass and active amplification paths. A single LNA block may have multiple individual LNA circuits coupled in parallel but in a compact configuration.

### First Embodiment—Dedicated Bypass Path

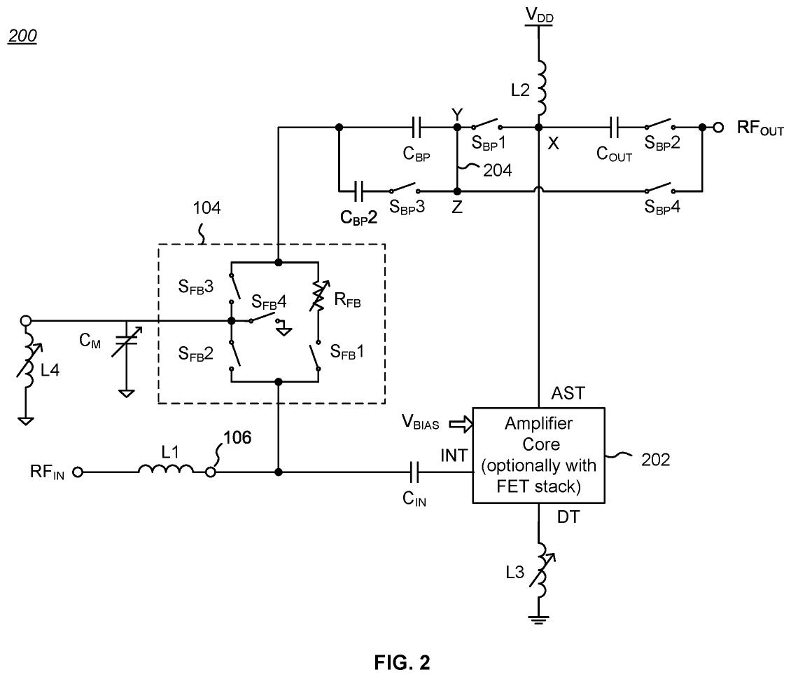

FIG. 2 is a simplified schematic diagram of a first embodiment of an LNA circuit 200 with improved wide-band performance. The improved wide-band performance is provided in part by a bypass path that optionally does not pass through an impedance matching network and thus has a dedicated path to RF_{OUT}.

In the illustrated example, the LNA circuit 200 includes an amplifier core 202. An RF input signal applied to an RF input terminal RF_{IN} is coupled through a series input matching inductor L1 and a DC blocking capacitor C_{IN} to the input terminal INT of the amplification core 202. Suitable bias voltages V_{BIAS} may be provided for the FETs within the amplification core 202. The amplified-signal terminal AST is coupled to an inductor L2 at a node X, which is also coupled to a voltage source V_{DD}. A degeneration inductor L3 is coupled between the degeneration terminal DT of the amplification core 202 and a reference potential, such as circuit ground. In the illustrated embodiment, the amplifier core optionally may include a FET stack and the inductor L3 may be a variable inductor (see below for examples of a FET stack and variable inductor configurations). An adjustable degeneration inductor L3 may be used to improve linearity in low gain modes. For example, a smaller value for the degeneration inductor L3 may be used in a high gain mode or modes, and a larger value for the degeneration inductor L3 may be used in a low gain mode or modes.

The LNA circuit 200 includes a bypass/IM feedback circuit 104 coupled between the amplified-signal terminal AST (through a capacitor C_{BP}) and the input terminal INT (through capacitor C_{IN}). An IM feedback portion of the bypass/IM feedback circuit 104 may be enabled by closing switch S_{FB}1 and disabled by opening switch S_{FB}1. In various gain modes, the in-circuit presence of resistor R_{FB} allows the Q-factor of the input impedance matching to be reduced, which increases the bandwidth of the LNA circuit 200 at the expense of gain and NF (see below for an example of a variable resistance configuration of the bypass/IM feedback circuit 104). Note that introduced feedback will naturally improve the system bandwidth as well. An advantage of using a variable or multi-state bypass/IM feedback circuit 104 is that multiple resistance values enable multiple gain modes. For instance, LNAs in mobile RF receiver devices may need multiple gain modes depending upon the range of input signal strength at the receiver. In addition, enabling multiple gain modes by using a variable or multi-state feedback resistor R_{FB} may eliminate the need for an output attenuator (common in conventional receiver LNAs).

A bypass portion of the bypass/IM feedback circuit 104 accommodates strong RF input signals that do not need amplification, allowing such signals to be coupled more directly to RF_{OUT}. The bypass portion includes switches S_{FB}2 and S_{FB}3 coupled in series between capacitor C_{BP} and capacitor C_{IN}. An AC ground is coupled by a switch S_{FB}4 to a midpoint node between switches S_{FB}2 and S_{FB}3. Switches S_{FB}2 and S_{FB}3 may both be CLOSED and switch S_{FB}4 OPENED to create a passive AC bypass path through switches S_{FB}2 and S_{FB}3. When the bypass mode is OFF, switches S_{FB}2 and S_{FB}3 are OPEN and switch S_{FB}4 is CLOSED to improve isolation.

An added matching inductor L4 is coupled to the midpoint node between switches S_{FB}2 and S_{FB}3. When the passive bypass path is enabled, the matching inductor L4 resonates the parasitic capacitance at the node where inductor L4 is connected to improve the Q of the bypass path, thus reducing loss. The matching inductor L4 may be a fixed inductor or may be a variable inductor (as illustrated), which enables greater flexibility in lower frequency band matching (see below for an example of a variable inductor configuration). The matching inductor L4 may be an on-chip component, but typically would be an off-chip component to accommodate different applications. Also coupled to the midpoint node between switches S_{FB}2 and S_{FB}3 is a matching capacitor C_{M}, which preferably is on-chip and may be a fixed capacitor or may be a variable capacitor (as illustrated). The matching capacitor Cy enables greater flexibility in wide-band matching (see below for an example of a variable capacitor configuration).

The capacitor C_{BP} is coupled to node X (and thus to capacitor C_{OUT}) through a switch S_{BP}1. Capacitor C_{OUT} is coupled to RF_{OUT} through a switch S_{BP}2. In addition, a second path from the bypass/IM feedback circuit 104 to RF_{OUT} is provided through capacitor C_{BP}2, switch S_{BP}3, and switch S_{BP}4, as well as through capacitor C_{BP} (which is coupled in parallel with capacitor C_{BP}2 when switch S_{BP}3 is closed). A shunt connection 204 couples a node Y between capacitor C_{BP} and switch S_{BP}1 to a node Z between switch S_{BP}3 and switch S_{BP}4.

In a first mode of operation, in which IM feedback is enabled, switches S_{FB}2 and S_{FB}3 are OPEN and switches S_{FB}1 and S_{FB}4 are CLOSED in the bypass/IM feedback circuit 104, and switches S_{BP}1 and S_{BP}2 are CLOSED and switches S_{BP}3 and S_{BP}4 are OPEN. Feedback is thus provided from the amplified-signal terminal AST (through capacitor C_{BP}) to the input terminal INT (through capacitor C_{IN}). In a variant of the first mode of operation, if stronger feedback is needed, then switch S_{BP}3 may be CLOSED, allowing feedback through capacitor C_{BP} as well.

Several primary modes of bypass operation are available by setting switches S_{FB}2 and S_{FB}3 to CLOSED and switches S_{FB}1 and S_{FB}4 to OPEN in the bypass/IM feedback circuit 104 (i.e., the bypass/IM feedback circuit 104 is set to a “BYPASS” state). For example, in a first bypass mode in which a first bypass path is enabled, the bypass/IM feedback circuit 104 is set to the BYPASS state, switches S_{BP}1 and S_{BP}2 are CLOSED, and switches S_{BP}3 and S_{BP}4 are OPEN. Accordingly, this mode enables a bypass path that allows RF input signals to propagate through inductor L1, the bypass/IM feedback circuit 104, and capacitors C_{BP} and C_{OUT} to RF_{OUT}.

In a second mode of operation in which a second bypass path is enabled, the bypass/IM feedback circuit 104 is set to the BYPASS state, switches S_{BP}1, S_{BP}2, and S_{BP}3 are CLOSED, and switch S_{BP}4 is OPEN. This configuration couples capacitors C_{BP} and C_{BP}2 in parallel due to the shunt connection 204. Accordingly, this mode enables a bypass path that allows RF input signals to propagate through inductor L1, the bypass/IM feedback circuit 104, parallel capacitors C_{BP} and C_{BP}2, and capacitor C_{OUT} to RF_{OUT}. In some embodiments and some modes, inductor L2 may influence the RF signal passing to RF_{OUT}.

In a third mode of operation in which a third bypass path is enabled, the bypass/IM feedback circuit 104 is set to the BYPASS state, switch S_{BP}4 is CLOSED, and switches S_{BP}1, S_{BP}2, and S_{BP}3 are OPEN. Accordingly, this mode enables a bypass path that allows RF input signals to propagate through inductor L1, the bypass/IM feedback circuit 104, and capacitor C_{BP} to RF_{OUT} (through shunt connection 204), thus bypassing capacitor C_{OUT} and avoiding the impedance matching network comprising inductor L2 and capacitor C_{OUT}.

In a fourth mode of operation in which a fourth bypass path is enabled, the bypass/IM feedback circuit 104 is set to the BYPASS state, switches S_{BP}3 and S_{BP}4 are CLOSED, and switches S_{BP}1 and S_{BP}2 are OPEN. This configuration couples capacitors C_{BP} and C_{BP}2 in parallel due to the shunt connection 204. Accordingly, this mode enables a bypass path that allows RF input signals to propagate through inductor L1, the bypass/IM feedback circuit 104, and parallel capacitors C_{BP} and C_{BP}2 to RF_{OUT}, bypassing capacitor C_{OUT} (thus avoiding the impedance matching network comprising inductor L2 and capacitor C_{OUT}).

As should be appreciated, in light of the number of controllable switches S_{FB}1-S_{FB}3 and S_{BP}1-S_{BP}4, some additional modes of operation may be available that may be useful in particular applications.

Note that the LNA amplifier core 202 may be turned OFF in any of the bypass modes to save current. The LNA amplifier core 202 may be turned OFF, for example, by setting the bias voltage for the input common-source FET M_{CS} to ground. However, turning the LNA amplifier core 202 OFF is not required—there may be cases where it is desirable to keep the LNA amplifier core 202 ON in order to reduce gain switching time.

Selection of a mode of operation generally depends on whether a bypass path is needed, and the frequency of the input signal. For example, at high frequencies and signal strengths, the third or fourth bypass modes of operation may be preferred, since either mode avoids the impedance matching network comprising inductor L2 and capacitor C_{OUT}. Modeling the LNA circuit 200 and testing the available modes of operation over a range of frequency may determine optimal selection of modes. A controller (not shown, but a common component) coupled to the various switches controls the OPEN or CLOSED states of those switches in response to external commands and/or to provided system information, such as selected frequency band, signal strength, etc.

TABLE 2 summarizes the passive mode negative gain for two modeled embodiments of the LNA circuit 200.

TABLE 2

| | Center of Band Gain (dB) | Center of Band Gain (dB) |
|---|---|---|
| Band (GHz) | [with fixed L4] | [with variable L4] |
| 1.4-1.5 | −5.41 | −4.81 |
| 1.8-2.0 | −3.76 | −4.11 |
| 2.0-2.2 | −3.26 | −3.69 |
| 2.3-2.4 | −3.93 | −3.95 |
| 2.5-2.7 | −4.38 | −4.42 |

### Variable Inductor and Variable Capacitor Circuits

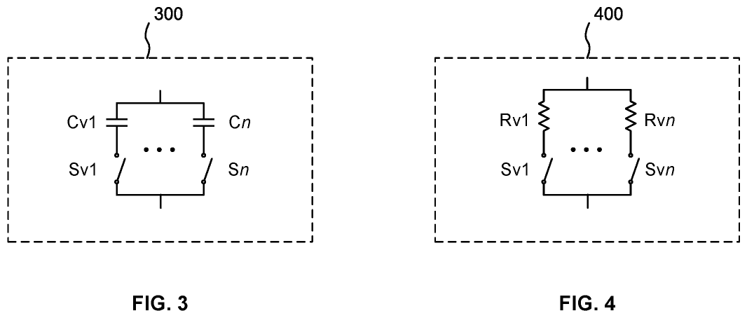

Reference was made above to variable capacitors, variable resistors, variable inductors, and FET stacks. FIG. 3 is a schematic diagram of an example variable capacitor circuit 300. A plurality of capacitors Cv1-Cvn (where n≥2) are respectively coupled in series with corresponding switches Sv1-Svn, and all of the series-coupled capacitor/switch pairs are coupled in parallel. The switches Sv1-Svn generally would be opened or closed by corresponding digital control signals. Accordingly, different capacitors or sets of capacitors may be selected to be electrically connected in parallel, providing the desired capacitance variability.

FIG. 4 is a schematic diagram of an example variable resistor circuit 400. A plurality of resistors Rv1-Rvn (where n≥2) are respectively coupled in series with corresponding switches Sv1-Svn, and all of the series-coupled resistor/switch pairs are coupled in parallel. The switches Sv1-Svn generally would be opened or closed by corresponding digital control signals. Accordingly, different resistors or sets of resistors may be selected to be electrically connected in parallel, providing the desired resistance variability.

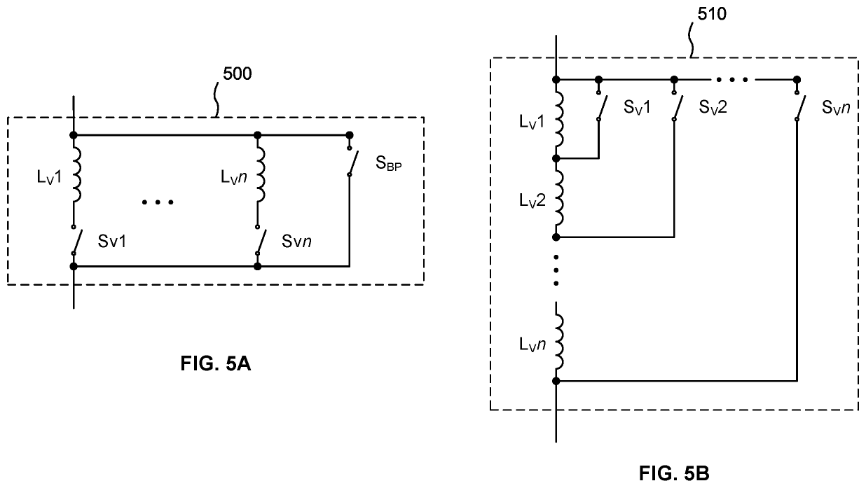

FIG. 5A is a schematic diagram of a first example variable inductor circuit 500. A plurality of inductors L_{V}1-L_{V}n (where n≥2) are respectively coupled in series with corresponding switches Sv1-Svn, and all of the series-coupled inductor/switch pairs are coupled in parallel. The switches Sv1-Svn generally would be opened or closed by corresponding digital control signals. Accordingly, different inductors or sets of inductors may be selected to be electrically connected in parallel, providing the desired inductance variability. In some embodiments, a bypass switch S_{BP} may be provided to bypass all of the inductors L_{V}1-L_{V}n.

FIG. 5B is a schematic diagram of a second example variable inductor circuit 510. A plurality of inductors L_{V}1-L_{V}n (where n≥2) are respectively coupled in series. Switches Sv1-Svn, are coupled in parallel with corresponding inductors L_{V}1-L_{V}n. The switches S_{V}1-S_{V}n generally would be opened or closed by corresponding digital control signals. Accordingly, different inductors or sets of inductors may be selected to be electrically connected in series, providing the desired inductance variability. For example, opening all of the switches S_{V}1-S_{V}n would provide a total series inductance of L_{V}1+ . . . +L_{V}n, while closing switch S_{V}n S_{BP} would bypass all of the inductors, giving a total inductance of zero. Note that a multi-port spiral inductor may be particularly useful in implementing the variable inductor circuit of FIG. 5B.

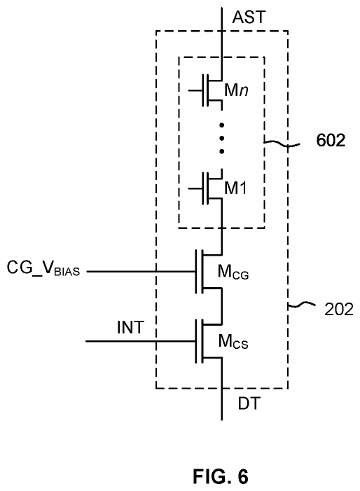

FIG. 6 is a schematic diagram of an example amplifier core 202 that may include a FET stack 602. The FET stack 602 includes a plurality of FETs M1-Mn (where n≥1) coupled in series source-to-drain between the amplified-signal terminal AST of the amplification core 202 and the drain of the common-gate FET M_{CG}. FETs M1-Mn would typically have a common gate bias. Including the optional FET stack 602 in some embodiments can overcome a relatively low breakdown voltage per CMOS FET. The amplified-signal terminal AST would then be coupled to the drain of the upper-most common-gate FET in the FET stack 602 of the amplification core 202.

### Second Embodiment—Bypass of Input Matching Inductor

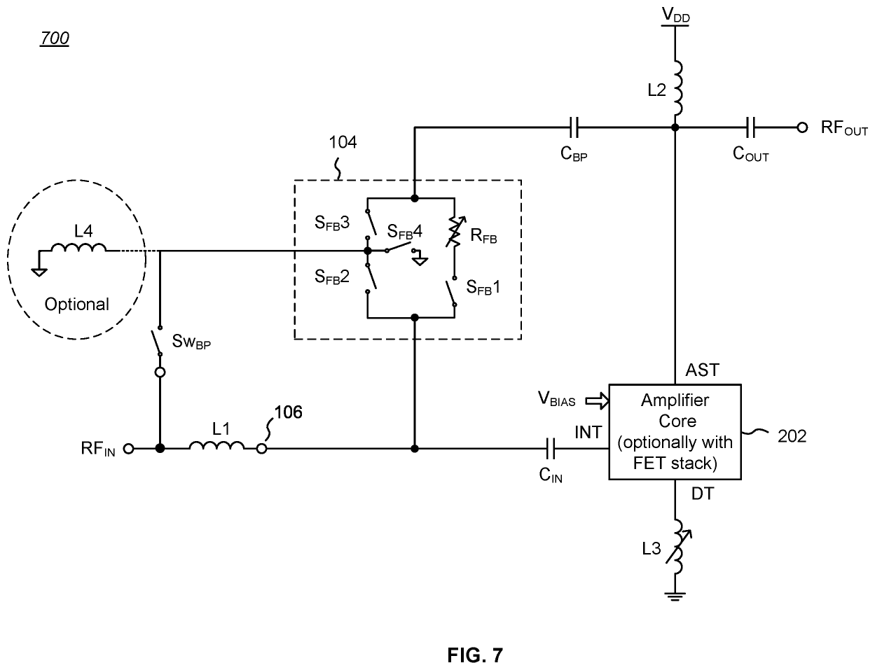

FIG. 7 is a simplified schematic diagram of a second embodiment of an LNA circuit 700 with improved wide-band performance. The improved wide-band performance is provided in part by a bypass path that does not pass through an input inductor.

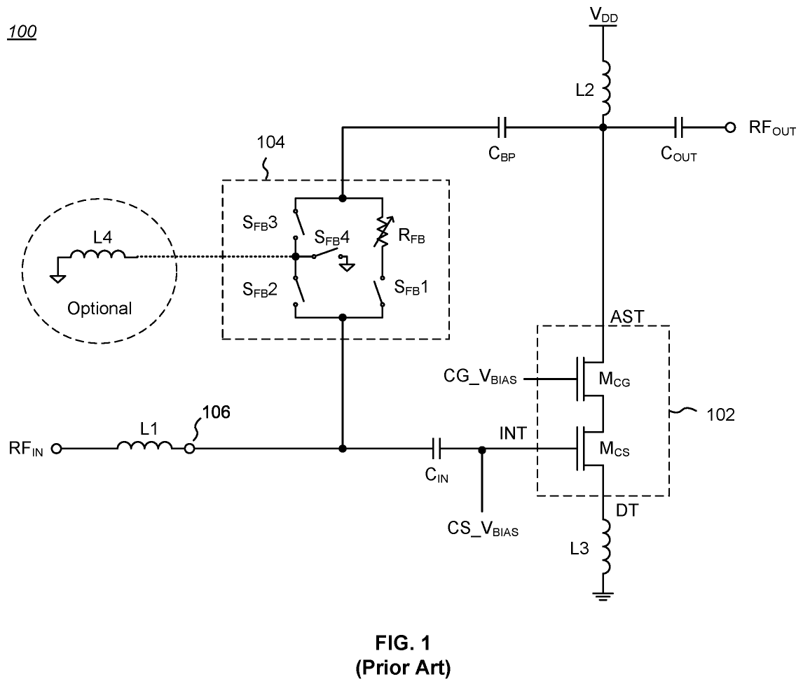

In the illustrated example, the LNA circuit 700 is similar in many aspects to the LNA circuit 100 of FIG. 1, except that the amplifier core 202 optionally may include a FET stack and the degeneration inductor L3 may be a variable inductor. In addition, a bypass switch Sw_{BP} is coupled between the input terminal RF_{IN} and the midpoint node between switches S_{FB}2 and S_{FB}3. Further, the bypass/IM feedback circuit 104 may have two BYPASS states: a first state in which switch S_{FB}3 is CLOSED and switches S_{FB}1, S_{FB}2, and S_{FB}4 are OPEN, and a second state in which switches S_{FB}2 and S_{FB}3 are CLOSED and switches S_{FB}1 and S_{FB}4 are OPEN (in which case the LNA circuit 700 may be operated in the same manner as the LNA circuit 100 of FIG. 1). In alternative embodiments, switch S_{FB}2 may be permanently set to an OPEN state or omitted entirely, in which case only the first BYPASS state is available.

In a first bypass mode of operation, the bypass/IM feedback circuit 104 is set to the first BYPASS state and switch Sw_{BP} is CLOSED. Accordingly, this mode enables a bypass path that allows RF input signals to propagate through the bypass/IM feedback circuit 104 and capacitors C_{BP} and C_{OUT} to RF_{OUT}, bypassing the input inductor L1.

In some embodiments, an optional added matching inductor L4 may be coupled to the midpoint node between switches S_{FB}2 and S_{FB}3 to provide better matching. The optional matching inductor L4 preferably is on-chip (but may be off-chip) and may be a fixed inductor (as illustrated), or may be a variable inductor to provide greater flexibility in matching.

Selection of a mode of operation generally depends on whether a bypass path is needed, and the frequency of the input signal. Modeling the LNA circuit 700 and testing the available modes of operation over a range of frequency may determine optimal selection of modes. A controller (not shown, but a common component) coupled to the various switches controls the OPEN or CLOSED states of those switches in response to external commands and/or to provided system information, such as selected frequency band, signal strength, etc.

### Third Embodiment—Bypass of Input Matching Inductor & Dedicated Bypass Path

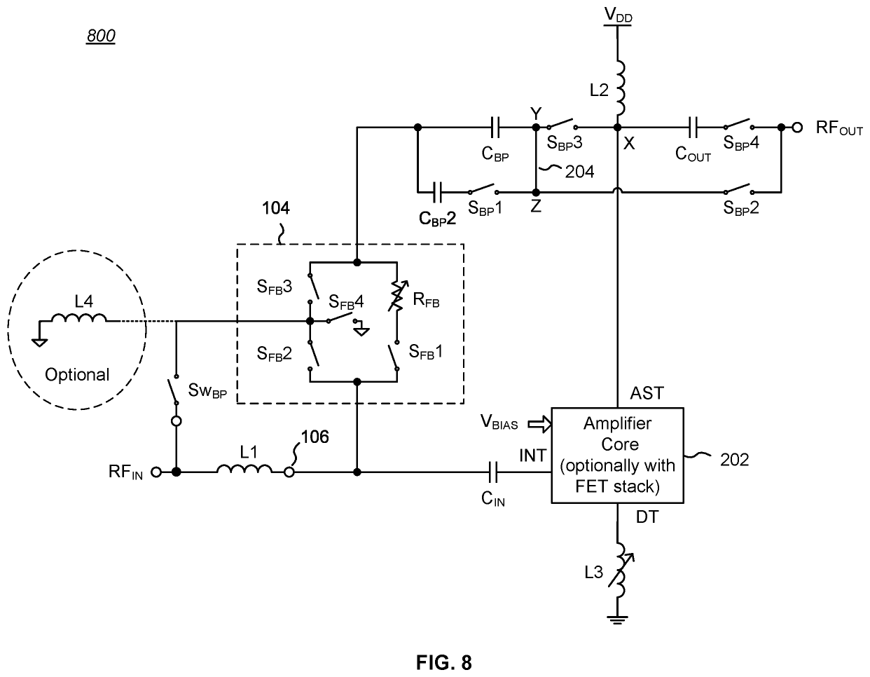

FIG. 8 is a simplified schematic diagram of a third embodiment of an LNA circuit 800 with improved wide-band performance. The improved wide-band performance is provided by a bypass path that has a first portion that optionally does not pass through an impedance matching network and thus has a dedicated path to RF_{OUT}, and a second portion that does not pass through an input inductor.

In the illustrated example, the LNA circuit 800 is essentially a combination of the LNA circuit 200 of FIG. 2 and the LNA circuit 700 of FIG. 7, and accordingly all of the bypass modes of those circuits are available for selection.

TABLE 3 summarizes the passive mode negative gain for one modeled embodiment of the LNA circuit 800.

TABLE 3

| Band (GHz) | Center of Band Gain (dB) |
|---|---|
| 1.4-1.5 | −3.699 |
| 1.8-2.0 | −3.451 |
| 2.0-2.2 | −3.276 |
| 2.3-2.4 | −3.303 |
| 2.5-2.7 | −3.321 |

### Fourth Embodiment—Selective Use of Load Inductor

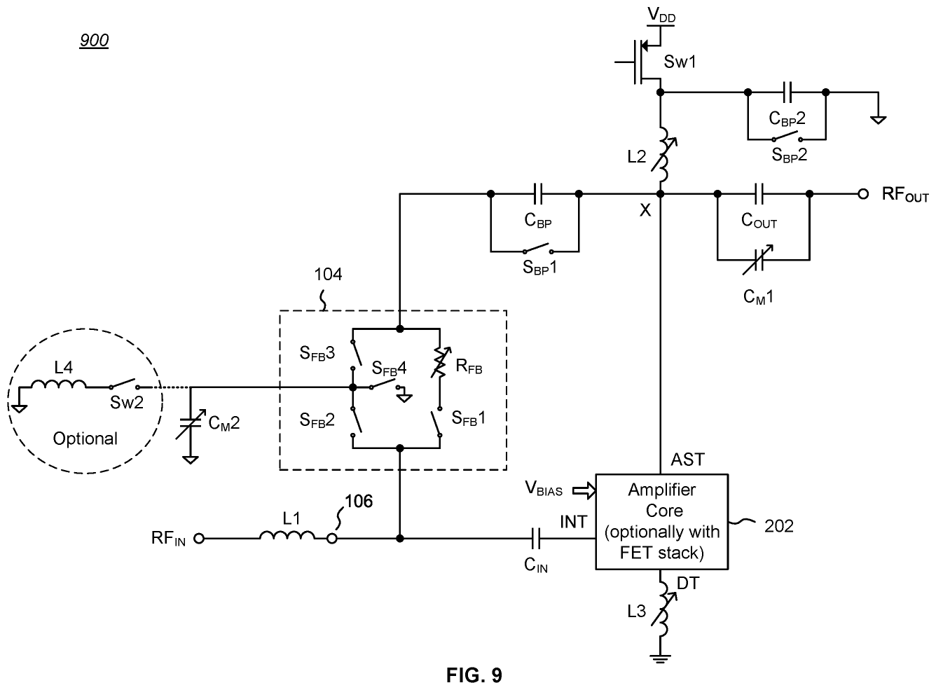

FIG. 9 is a simplified schematic diagram of a fourth embodiment of an LNA circuit 900 with improved wide-band performance. The improved wide-band performance is provided in part by selectively disabling a load inductor in some modes of operation.

In the illustrated example, the LNA circuit 900 includes an amplifier core 202. An RF input signal applied to an RF input terminal RF_{IN} is coupled through a series input matching inductor L1 and a DC blocking capacitor C_{IN} to the input terminal INT of the amplification core 202. Suitable bias voltages V_{BIAS} may be provided for the FETs within the amplification core 202. The amplified-signal terminal AST is coupled to a load inductor L2 at a node X, which is also coupled to a voltage source V_{DD} through a mode switch Sw1. Inductor L2 may be a fixed inductor or may be a variable inductor (as illustrated). An inductor L3 is coupled between the degeneration terminal DT of the amplification core 202 and a reference potential, such as circuit ground. In the illustrated embodiment, the amplifier core 202 optionally may include a FET stack, and the inductor L3 may be a variable inductor.

The LNA circuit 900 includes a bypass/IM feedback circuit 104 coupled between the amplified-signal terminal AST (through a capacitor C_{BP}) and the input terminal INT (through capacitor C_{IN}). A first bypass switch S_{BP}1 is coupled in parallel with capacitor C_{BP}. A capacitor C_{BP}2 is coupled from a node between the mode switch Sw1 and inductor L2 to a reference potential. A second bypass switch S_{BP}2 is coupled in parallel with capacitor C_{BP}2 (note that bypass switch S_{BP}2 and capacitor C_{BP}2 are in different locations compared to like-named elements in other figures). A capacitor C_{OUT} is coupled between node X and the output terminal RF_{OUT}. In some embodiments, a variable matching capacitor C_{M}1 is coupled in parallel with capacitor C_{OUT} to provide greater flexibility in matching.

Coupled to the midpoint node between switches S_{FB}2 and S_{FB}3 is a matching capacitor C_{M}2, which preferably is on-chip (but may be off-chip) and may be a fixed capacitor or may be a variable capacitor (as illustrated). Capacitor C_{M}2 enables greater flexibility in wide-band matching.

In some embodiments, an optional selectable matching inductor L4 may be coupled to the midpoint node between switches S_{FB}2 and S_{FB}3 through a connecting switch Sw2 to provide greater flexibility in matching. The optional matching inductor L4, which preferably is on-chip (but may be off-chip), may be a fixed inductor (as illustrated), or may be a variable inductor to provide greater flexibility in matching.

For a non-bypass mode of operation, the IM feedback portion of the bypass/IM feedback circuit 104 is enabled (meaning switches S_{FB}2 and S_{FB}3 are OPEN and switches S_{FB}1 and S_{FB}4 are CLOSED), switch Sw1 is CLOSED, and switches Sw2, S_{BP}1, and S_{BP}2 are OPEN.

In a first bypass mode of operation, the bypass/IM feedback circuit 104 is set to a BYPASS state (meaning switches S_{FB}2 and S_{FB}3 are CLOSED and switches S_{FB}1 and S_{FB}4 are OPEN), switches Sw1, Sw2, and S_{BP}2 are OPEN, and switch S_{BP}1 is CLOSED.

In a second bypass mode of operation, which may be particularly useful for higher frequency bands (e.g., 2.3-2.7 GHZ), the bypass/IM feedback circuit 104 is set to a BYPASS state, switches Sw1 and S_{BP}2 are OPEN, and switches Sw2 and S_{BP}1 is CLOSED.

In a third bypass mode of operation, which may be particularly useful for lower frequency bands (e.g., 1.4-2.2 GHZ), the bypass/IM feedback circuit 104 is set to a BYPASS state, switches Sw1 and Sw2 are OPEN, and switches S_{BP}1 and S_{BP}2 are CLOSED.

Note that in all three of the example bypass modes of operation, the inductor L2 is disconnected from V_{DD} by opening switch Sw1. As should be appreciated, in light of the number of controllable switches, some additional modes of operation may be available that may be useful in particular applications.

Advantages of the LNA circuit 900 include: a minimum impact on active gain states; no additional inductor needed at all (i.e., the optional matching inductor L4 may be omitted entirely); and the LNA circuit size is kept small as only a few switches and logic cells are used.

TABLE 4 summarizes the passive mode negative gain for two modeled embodiments of the LNA circuit 900.

TABLE 4

| | Gain Center (dB) | Gain Center (dB) |
|---|---|---|
| Band (GHz) | [without L4] | [with L4] |
| 1.4-1.5 | −7.61 | −7.68 |
| 1.8-2.0 | −5.75 | −6.12 |
| 2.0-2.2 | −5.63 | −6.09 |
| 2.3-2.4 | −6.31 | −6.02 |
| 2.5-2.7 | −7.78 | −4.63 |

### Circuit Embodiments

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

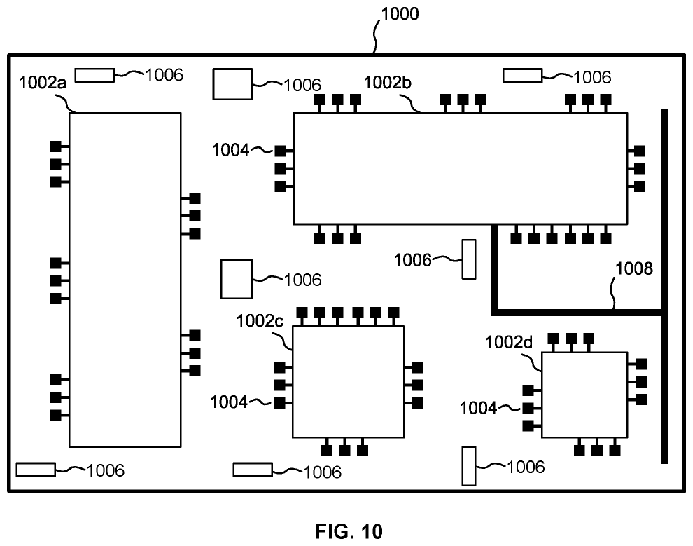

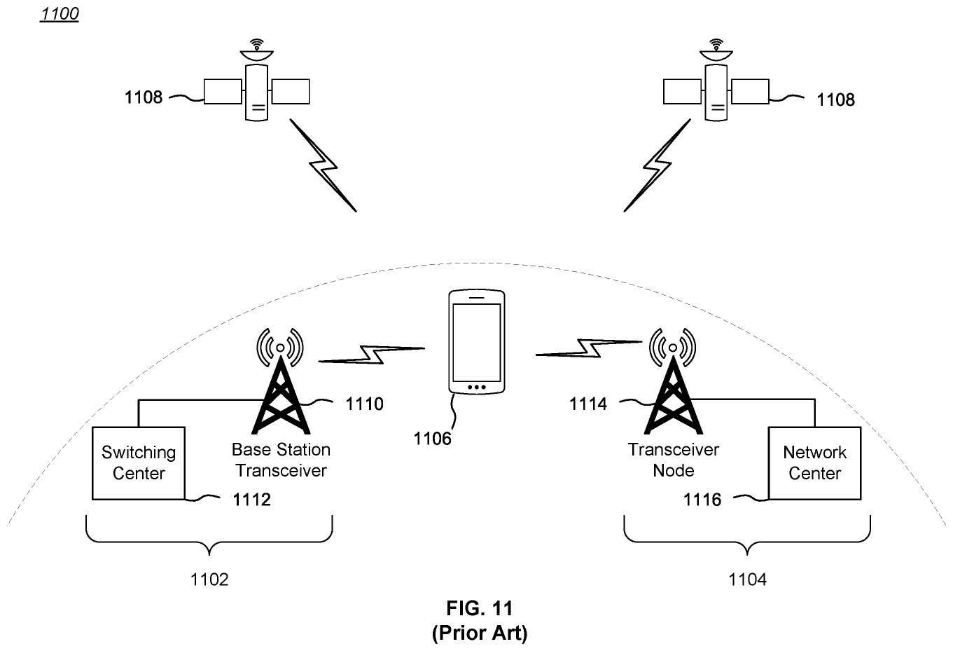

As one example of further integration of embodiments of the present invention with other components, FIG. 10 is a top plan view of a substrate 1000 that may be, for example, a printed circuit board or chip module substrate (e.g., a thin-film tile). In the illustrated example, the substrate 1000 includes multiple ICs 1002a-1002d having terminal pads 1004 which would be interconnected by conductive vias and/or traces on and/or within the substrate 1000 or on the opposite (back) surface of the substrate 1000 (to avoid clutter, the surface conductive traces are not shown and not all terminal pads are labelled). The ICs 1002a-1002d may embody, for example, signal switches, active and/or passive filters, amplifiers (including one or more LNAs), and other circuitry. For example, IC 1002b may incorporate one or more instances of an LNA circuit like the novel LNA circuits disclosed above.

The substrate 1000 may also include one or more passive devices 1006 embedded in, formed on, and/or affixed to the substrate 1000. While shown as generic rectangles, the passive devices 1006 may be, for example, filters, capacitors, inductors, transmission lines, resistors, planar antennae elements, transducers (including, for example, MEMS-based transducers, such as accelerometers, gyroscopes, microphones, pressure sensors, etc.), batteries, etc., interconnected by conductive traces on or in the substrate 1000 to other passive devices 1006 and/or the individual ICs 1002a-1002d.

The front or back surface of the substrate 1000 may be used as a location for the formation of other structures. For example, one or more antennae may be formed on or affixed to the front or back surface of the substrate 1000; one example of a front-surface antenna 1008 is shown, coupled to an IC die 1002b, which may include RF front-end circuitry. Thus, by including one or more antennae on the substrate 1000, a complete radio may be created.

### System Aspects

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G New Radio, 6G, and WiFi (e.g., 802.11a, b, g, ac, ax, be) protocols, as well as other radio communication standards and protocols.

As an example of wireless RF system usage, FIG. 11 illustrates a prior art wireless communication environment 1100 comprising different wireless communication systems 1102 and 1104, and which may include one or more mobile wireless devices 1106. A wireless device 1106 may be a cellular phone, a wireless-enabled computer or tablet, or some other wireless communication unit or device. A wireless device 1106 may also be referred to as a mobile station, user equipment, an access terminal, or some other terminology known in the telecommunications industry.

A wireless device 1106 may be capable of communicating with multiple wireless communication systems 1102, 1104 using one or more of telecommunication protocols such as the protocols noted above. A wireless device 1106 also may be capable of communicating with one or more satellites 1108, such as navigation satellites (e.g., GPS) and/or telecommunication satellites. The wireless device 1106 may be equipped with multiple antennas, externally and/or internally, for operation on different frequencies and/or to provide diversity against deleterious path effects such as fading and multi-path interference.

The wireless communication system 1102 may be, for example, a CDMA-based system that includes one or more base station transceivers (BSTs) 1110 and at least one switching center (SC) 1112. Each BST 1110 provides over-the-air RF communication for wireless devices 1106 within its coverage area. The SC 1112 couples to one or more BSTs 1110 in the wireless system 1102 and provides coordination and control for those BSTs 1110.

The wireless communication system 1104 may be, for example, a TDMA-based system that includes one or more transceiver nodes 1114 and a network center (NC) 1116. Each transceiver node 1114 provides over-the-air RF communication for wireless devices 1106 within its coverage area. The NC 1116 couples to one or more transceiver nodes 1114 in the wireless system 1104 and provides coordination and control for those transceiver nodes 1114.

In general, each BST 1110 and transceiver node 1114 is a fixed station that provides communication coverage for wireless devices 1106, and may also be referred to as base stations or some other terminology known in the telecommunications industry. The SC 1112 and the NC 1116 are network entities that provide coordination and control for the base stations and may also be referred to by other terminologies known in the telecommunications industry.

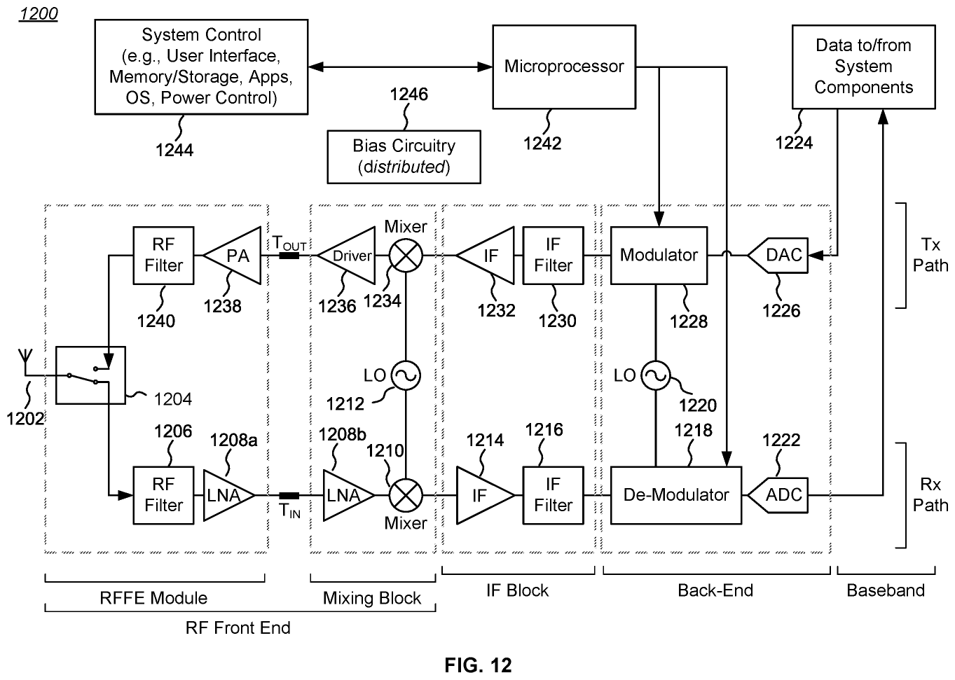

An important aspect of any wireless system, including the systems shown in FIG. 11, is in the details of how the component elements of the system perform. FIG. 12 is a block diagram of a transceiver 1200 that might be used in a wireless device, such as a cellular telephone, and which may beneficially incorporate an embodiment of the present invention for improved performance. As illustrated, the transceiver 1200 includes a mix of RF analog circuitry for directly conveying and/or transforming signals on an RF signal path, non-RF analog circuitry for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines TIN and Tour (e.g., microstrips, co-planar waveguides, or an equivalent structure or circuit), either or both of which may have, for example, a 50Ω impedance.

The receiver path Rx receives over-the-air RF signals through at least one antenna 1202 and a switching unit 1204, which may be implemented with active switching devices (e.g., field effect transistors or FETs) and/or with passive devices that implement frequency-domain multiplexing, such as a diplexer or duplexer. An RF filter 1206 passes desired received RF signals to at least one low noise amplifier (LNA) 1208a, the output of which is coupled from the RFFE Module to at least one LNA 1208b in the Mixing Block (through transmission line TIN in this example). The LNA(s) 1208b may provide buffering, input matching, and reverse isolation. In some embodiments, the LNA(s) 1208a and 1208b may be a single LNA, and in any case may be instances of the novel LNAs disclosed above.

The output of the LNA(s) 1208b is combined in a corresponding mixer 1210 with the output of a first local oscillator 1212 to produce an IF signal. The IF signal may be amplified by an IF amplifier 1214 and subjected to an IF filter 1216 before being applied to a demodulator 1218, which may be coupled to a second local oscillator 1220. The demodulated output of the demodulator 1218 is transformed to a digital signal by an analog-to-digital converter 1222 and provided to one or more system components 1224 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 1224 is transformed to an analog signal by a digital-to-analog converter 1226, the output of which is applied to a modulator 1228, which also may be coupled to the second local oscillator 1220. The modulated output of the modulator 1228 may be subjected to an IF filter 1230 before being amplified by an IF amplifier 1232. The output of the IF amplifier 1232 is then combined in a mixer 1234 with the output of the first local oscillator 1212 to produce an RF signal. The RF signal may be amplified by a driver 1236, the output of which is coupled to a power amplifier (PA) 1238 (through transmission line Tour in this example). The amplified RF signal may be coupled to an RF filter 1240, the output of which is coupled to at least one antenna 1202 through the switching unit 1204.

The operation of the transceiver 1200 is controlled by a microprocessor 1242 in known fashion, which interacts with system control components 1244 (e.g., user interfaces, memory/storage devices, application programs, operating system software, power control, etc.). In addition, the transceiver 1200 will generally include other circuitry, such as bias circuitry 1246 (which may be distributed throughout the transceiver 1200 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 1200 may be positioned in a different order (e.g., filters) or omitted. Other components can be (and often are) added, such as (by way of example only) additional filters, impedance matching networks, variable phase shifters/attenuators, power dividers, etc.

As discussed above, the current invention improves better wide-band RF performance than conventional designs. As a person of ordinary skill in the art will understand, a system architecture is beneficially impacted by the current invention in critical ways, including better range, better reception, lower power, longer battery life, and wider bandwidth.

### Methods

Another aspect of the invention includes methods for improving passive mode negative gain performance in an amplifier, particularly an LNA. For example, a first method of improving passive mode negative gain performance in an amplifier having an amplifier core coupled between an input terminal and an output terminal and having a load network coupled to the output terminal, includes providing a dedicated bypass path that enables propagation of an input radio frequency signal from the input terminal to the output terminal without connecting to the load network. A second method of improving passive mode negative gain performance in an amplifier having an amplifier core coupled to an input terminal through an input inductor, and having an output terminal and a load network coupled to the output terminal, includes providing a dedicated bypass path that enables propagation of an input radio frequency signal from the input terminal to the output terminal while bypassing the input inductor. A third method of improving passive mode negative gain performance in an amplifier having an amplifier core coupled to an input terminal through an input inductor, and having an output terminal and a load network coupled to the output terminal, includes providing a dedicated bypass path that enables propagation of an input radio frequency signal from the input terminal to the output terminal while bypassing the input inductor and/or providing a dedicated bypass path that enables propagation of an input radio frequency signal from the input terminal to the output terminal while bypassing the input inductor. A fourth method of improving passive mode negative gain performance in an amplifier having an amplifier core coupled between an input terminal and an output terminal and having a load inductor coupled to the output terminal, includes disabling the load inductor and enabling propagation of an input radio frequency signal from the input terminal to the output terminal.

### Fabrication Technologies & Options

While the example embodiments are LNAs, the inventive circuits and methods may also be applied to other types of amplifiers, such as power amplifiers.

It should be appreciated that the inventive architecture provides a great deal of flexibility in setting amplifier circuit component values and component states in order to achieve a variety of performance goals. For example, it may be that noise factor and input impedance matching in a maximum gain mode are to be emphasized. In other cases, it may be that linearity (IIP3) in a maximum gain mode is to be emphasized. In addition, appropriate bias levels for the amplification core 202 may be selected to ensure that the input impedance matching meets required specifications for a maximum gain mode.

Additional well-known circuit elements that might be included in some applications, such as bypass and/or DC blocking capacitors, are omitted for clarity.

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar junction transistor (BJT), BICMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### CONCLUSION

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. An amplifier including:
(a) an amplifier input terminal configured to receive a radio-frequency (RF) signal;
(b) an amplifier core including:
(1) an amplifier core input terminal configured to receive the RF signal through an input matching inductor coupled between the amplifier input terminal and the amplifier core input terminal; and
(2) an amplified-signal terminal;
(c) an amplifier output terminal;
(d) an impedance matching network coupled to the amplifier output terminal and to the amplified-signal terminal;
(e) a bypass circuit coupled between the amplified-signal terminal and the amplifier core input terminal, the bypass circuit including:
(1) a first switch and a second switch coupled in series, the first switch being coupled to the amplifier core input terminal;
(2) a bypass circuit node between the first switch and the second switch, the bypass circuit node configured to be coupled to a matching inductor;
(f) a matching capacitor coupled to the bypass circuit node; and
(g) a bypass circuit path coupled to the second switch of the bypass circuit, the impedance matching network, and the amplifier output terminal, the bypass circuit path configured to allow, in at least one bypass mode of operation, an RF signal to propagate from the bypass circuit to the amplifier output terminal while avoiding the impedance matching network.

2. The invention of claim 1, wherein the amplifier core includes a degeneration terminal, and further including a degeneration inductor coupled between the degeneration terminal and a reference potential.

3. The invention of claim 1, wherein the matching inductor is a variable inductor.

4. The invention of claim 1, wherein the matching capacitor is a variable capacitor.

5. The invention of claim 1, wherein the bypass circuit node is coupled to an AC ground.

6. The invention of claim 1, wherein the amplifier core includes a field-effect transistor stack.

7. The invention of claim 1, wherein the impedance matching network includes an output capacitor coupled to a load inductor.

8.-13. (canceled)

14. An amplifier including:
(a) an amplifier input terminal configured to receive a radio-frequency (RF) signal;
(b) an amplifier core including:
(1) an amplifier core input terminal configured to receive the RF signal through an input matching inductor coupled between the amplifier input terminal and the amplifier core input terminal; and
(2) an amplified-signal terminal;
(c) an amplifier output terminal;
(d) an impedance matching network coupled to the amplifier output terminal and to the amplified-signal terminal;
(e) a bypass capacitor coupled to the impedance matching network;
(f) a bypass circuit coupled between the bypass capacitor and the amplifier core input terminal, the bypass circuit including:
(1) a first switch and a second switch coupled in series, the first switch being coupled to the amplifier core input terminal and the second switch being coupled to the bypass capacitor;
(2) a bypass circuit node between the first switch and the second switch; and
(g) a bypass switch coupled between the amplifier input terminal and the bypass circuit node.

15. The invention of claim 12, wherein the amplifier core includes a degeneration terminal, and further including a degeneration inductor coupled between the degeneration terminal and a reference potential.

16. The invention of claim 12, wherein the bypass circuit node is configured to be coupled to a matching inductor.

17. (canceled)

18. The invention of claim 12, wherein the bypass circuit node is coupled to an AC ground.

19. The invention of claim 12, wherein the amplifier core includes a field-effect transistor stack.

20.-25. (canceled)

26. An amplifier including:
(a) an amplifier input terminal configured to receive a radio-frequency (RF) signal;
(b) an amplifier core including:
(1) an amplifier core input terminal configured to receive the RF signal through an input matching inductor coupled between the amplifier input terminal and the amplifier core input terminal; and
(2) an amplified-signal terminal;
(c) a first bypass capacitor coupled to the amplified-signal terminal;
(d) a first bypass switch coupled in parallel with the first bypass capacitor;
(e) a bypass circuit coupled between the bypass capacitor and the amplifier core input terminal, the bypass circuit including:
(3) a first switch and a second switch coupled in series, the first switch being coupled to the amplifier core input terminal;
(4) a bypass circuit node between the first switch and the second switch;
(f) a first matching capacitor coupled to the bypass circuit node;
(g) an amplifier output terminal;
(h) an output capacitor coupled between the amplified-signal terminal and the amplifier output terminal;
(i) a second matching capacitor coupled in parallel with the output capacitor;
(j) a load inductor coupled to a common node between the bypass capacitor and the output capacitor, the common node being coupled to the amplified-signal terminal of the amplifier core;
(k) a mode switch coupled to the load inductor and configured to be coupled to a voltage source;
(l) a second bypass capacitor coupled to a node between the mode switch and the load inductor, and to a reference potential; and
(m) a second bypass switch coupled in parallel with the second bypass capacitor.

27. The invention of claim 20, wherein the amplifier core includes a degeneration terminal, and further including a degeneration inductor coupled between the degeneration terminal and a reference potential.

28. The invention of claim 20, wherein the load inductor is a variable inductor.

29. The invention of claim 20, wherein the first matching capacitor is a variable capacitor.

30. The invention of claim 20, wherein the second matching capacitor is a variable capacitor.

31. The invention of claim 20, wherein the bypass circuit node is configured to be selectably coupled to a matching inductor through a connecting switch.

32. (canceled)

33. The invention of claim 20, wherein the bypass circuit node is coupled to an AC ground.

34. The invention of claim 20, wherein the amplifier core includes a field-effect transistor stack.

35.-38. (canceled)
